(19) United States
(12) Patent Application Publication
(10) Pub. No.: US 2008/0143367 A1
(43) Pub. Date: Jun. 19, 2008

(54) COMPLIANT ELECTRICAL CONTACT HAVING MAXIMIZED THE INTERNAL SPRING VOLUME

(76) Inventor: Scott Chabineau-Lovgren, Pomona, CA (US)

Correspondence Address: CHRISTIE, PARKER & HALE, LLP, PO BOX 7068, PASADENA, CA, 91109-7068, US

(21) Appl. No.: 11/945,984

(22) Filed: Nov. 27, 2007

Related U.S. Application Data
(60) Provisional application No. 60/875,048, filed on Dec. 14, 2006.

(51) Int. Cl. G01R 1/067

(52) U.S. Cl. 324/761

(57) ABSTRACT

A spring loaded electrical contact assembly for making a connection between two surfaces that consist of two U-shaped components axially opposed and rotated 90 degrees with respect to each other and configured to allow them to pass over each other while contacting in a wiping manner. When compressed to a test position, the components completely envelop a spring and provide a minimal solid height at maximum compliance while providing a low and reliable electrical contact.

### CROSS-REFERENCE TO RELATED APPLICATION(S)

This application claims the benefit of U.S. Provisional Patent Application Ser. No. 60/875,048, filed Dec. 14, 2006 and entitled COMPLIANT ELECTRICAL CONTACT HAVING MAXIMIZED THE INTERNAL SPRING VOLUME, the entire content of which is hereby expressly incorporated by reference.

### FIELD OF THE INVENTION

The present invention relates to electrical contact probes for forming electrical interconnects, and more particularly, to a compliant electrical contact probe assembly having two components with like sliding contact surfaces and latching geometry.

### BACKGROUND OF THE INVENTION

Conventional spring-loaded contact probes generally include a moveable plunger, a barrel having and open end for containing an enlarged diameter section or bearing of the plunger, and spring for biasing the travel of the plunger in the barrel. The plunger bearing slideably engages the inner surface of the barrel. The enlarged bearing section is retained in the barrel by a crimp near the barrel's open end.

The plunger is commonly biased outwardly a selected distance by the spring and may be biased or depressed inwardly into the barrel, a selected distance, under force directed against the spring. Axial and side biasing of the plunger against the barrel prevents false opens or intermittent points of no contact between the plunger and the barrel. The plunger generally is solid and includes a head, or tip, for contacting electrical devices under test. The barrel may also include a tip opposite the barrel's open end.

The barrel, plunger and tip form an electrical interconnect between the electrical device under test and test equipment and, as such, are manufactured from an electrically conductive material. Typically, probes are fitted in cavities formed through the thickness of a test plate or socket. Generally, a contact side of the electrical device to be tested, such as an integrated circuit, is brought in to pressure contact with the tips of the plungers protruding through one side of the test plate or test socket for maintaining spring pressure against the electrical device. A contact plate connected to the test equipment is brought to contact with the tips of the plungers protruding through the other side of the test plate or test socket. The test equipment transmits test signals to the contact plate from where they are transmitted through the test probe interconnects to the device being tested. After the electrical device has been tested, the pressure exerted by the spring probes is released and the device is removed from contact with the tip of each probe. In conventional systems, the pressure is released by moving the electrical device and probes away from one another, thereby allowing the plungers to be displaced outwardly away from the barrel under the force of the spring, until the enlarged diameter bearing of the plunger engages the crimp of the barrel.

The process of making a conventional spring probe involves separately producing the compression spring, the barrel and the plunger. The compression spring is wound and heat treated to produce a spring of a precise size and of a controlled spring force. The plunger is typically turned on a lathe and heat treated. The barrels are also sometimes heat treated. The barrels can be formed in a lathe, by a deep draw process, or a stamping process. All components may be subjected to a plating process to enhance conductivity. The spring probe components are assembled either manually or by an automated process.

An alternative type of conventional probe consists of two contact tips separated by a spring. Each contact tip is attached to a spring end. This type of probe relies on the walls of the test plate or socket cavity into which it is inserted for lateral support. The electrical path provided by this type of probe spirals down the spring wire between the two contact tips. Consequently, this probe has a relatively long electrical interconnect length which may result in attenuation of the high frequency signals when testing integrated circuits.

A problem with conventional spring probes and shelled type spring probes is that because one component slides within the other component, the spring diameter is limited by the size of the smaller component which reciprocates within the second component, i.e. the plunger within the barrel. Consequently, a maximize size spring cannot be utilized within the spring probe. Consequently, it is desirable to reduce the electrical interconnect length of a probe without reducing the spring volume. In addition, it is desirable to increase the spring volume without decreasing the spring compliance or increasing the electrical interconnect length. Moreover, it is desirable to have a probe that can be easily manufactured and assembled.

### SUMMARY OF THE INVENTION

The present invention is an improved electrical contact probe with compliant internal interconnect which has been designed to address the drawbacks of prior probe designs. The purpose of the invention is to provide a compliant electrical interconnect between a printed circuit board (PCB) and the external leads of an integrated circuit (IC) package or other electrical circuit, such as an electronic module, during functional testing of the devices. The probe of the present invention consists of two moving fabricated electrically conductive components with an electrically conductive compliant helical spring within the two components. The two components of the probe assembly have like sliding contact surfaces and latching geometry. One component is situated axially opposite and rotated 90 degrees forming a generally enclosed internal volume, which captivates the compression spring. Passage of the opposing latches over one another locks the components together, preventing disassembly, while allowing the contacting surfaces to slide unopposed during operation. Once compressed to the normal operation height, the assembly forms a nearly enclosed shell.

The design of the present invention allows for minimal solid height at maximum compliance while the connection points between the components are at the closest point possible to the opposing tips providing the shortest possible current path. The two components are generally “U” shaped and have external surfaces for sliding contact on the opposing sides of both elongated leg portions. From the sliding contact surface, an extended portion creates a latching mechanism that additionally creates internal surfaces for sliding contact. Each of the two components includes a retaining feature that allows the probe assembly to be retained in a housing having suitable geometry whereas to not allow the probe assembly to fall free of the housing. Contact between the two components is maintained by fabricating each component in such a fashion that the distance between the internal contact surfaces is smaller than the distance between external contact surfaces. In an alternative embodiment, tapered external contact surfaces increase the amount of contact as the assembly is compressed by forcing the opposing component leg portions apart.

Manufacturing methods for the present invention include turning, stamping, injection molding for other non-traditional manufacturing methods such as lithographic layering. The components will generally be manufactured in a cylindrical fashion, however square or rectangular shapes are possible depending upon the specific manufacturing technique.

The present invention maximizes the internal spring volume by allowing for additional spring volume that is otherwise taken up by a smaller bore in one of the components such as in prior art designs. The present invention also improves on external spring and conventional spring probe contacts by enveloping the spring with an external shell formed by the two components allowing a shorter test height and having the connection points between the components at the closest point possible to the opposing tips, thereby improving on high frequency and high current capabilities. A further improvement over conventional spring probes is by providing up to eight points of contact that carry electrical current through the assembly versus one to three points by conventional spring probes.

### BRIEF DESCRIPTION OF THE DRAWINGS

FIG. 1 is an perspective view showing the compliant electrical contact in its expanded and retracted positions;

FIG. 2 is a perspective view of one component of the electrical contact of FIG. 1;

FIG. 3 is perspective view of an alternative component of the electrical contact;

FIG. 4 is a perspective view of a second alternative embodiment component of the electrical contact;

FIG. 5 is a front view of a third alternative embodiment electrical contact; and

FIG. 6 is a schematic view of a stamping process for the component of FIG. 2.

### DETAILED DESCRIPTION

FIG. 1 illustrates the electrical contact 10 having maximized the internal spring volume of the present invention. The contact 10 consists of two identical components 12 and 14 which captivate a compression spring 16. Components 12 and 14 are axially aligned and rotated 90 degrees with respect to each other forming a generally enclosed internal volume which captivates the compression spring. As also shown in FIG. 2 which illustrates one of the components 14, each of the components is generally U-shaped having legs 18 and 20 and a contact portion 22. Each of the legs includes a sliding contact surface 24 which engages receiving surfaces 26. Sliding surface 24 and receiving surface 26 meet at a latch portion 28. Passing the opposing latches over each other locks the components together, preventing disassembly while allowing the contact surfaces to slide unopposed during operation. Once compressed to the normal operation height, the assembly forms a nearly enclosed shell. This design allows for a minimal solid height at maximum compliance while the connection points between the components are at the closest points possible to the opposing tips 22 providing the shortest possible current path. The U-shaped components utilize the external sliding surfaces or sliding contact on the opposing sides of both elongated leg portions wherein the extended portion creating the latch mechanism also additionally creates internal surfaces or sliding contact. The electrical contact design maximizes the internal spring volume while having a final compressed height as short as possible. The opposing tips 22 are designed to be as thin as possible to reduce the overall length of the electrical contact.

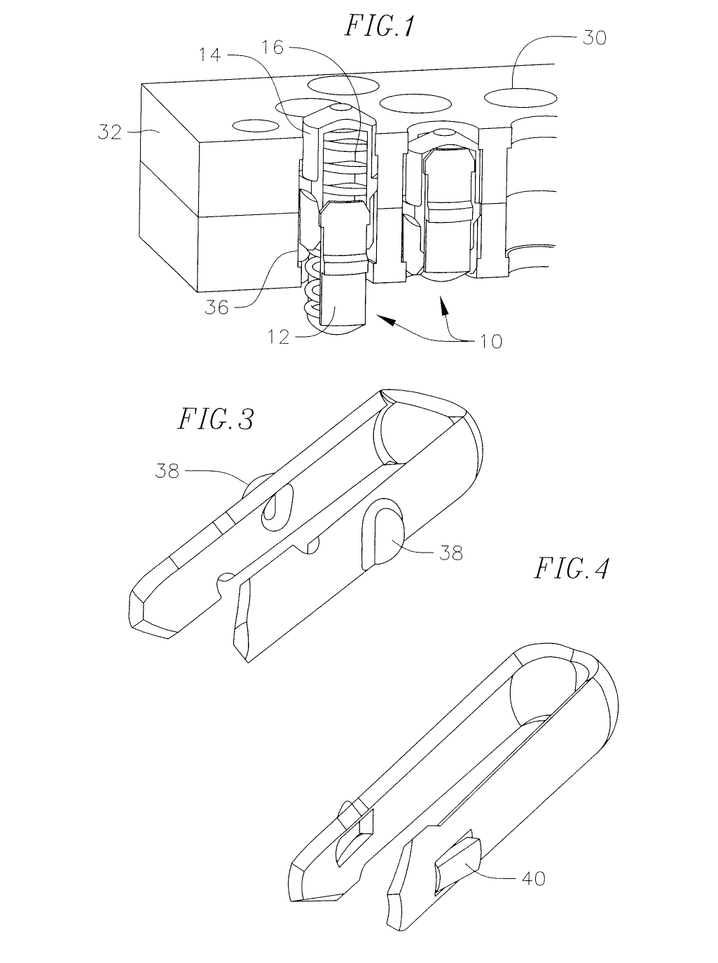

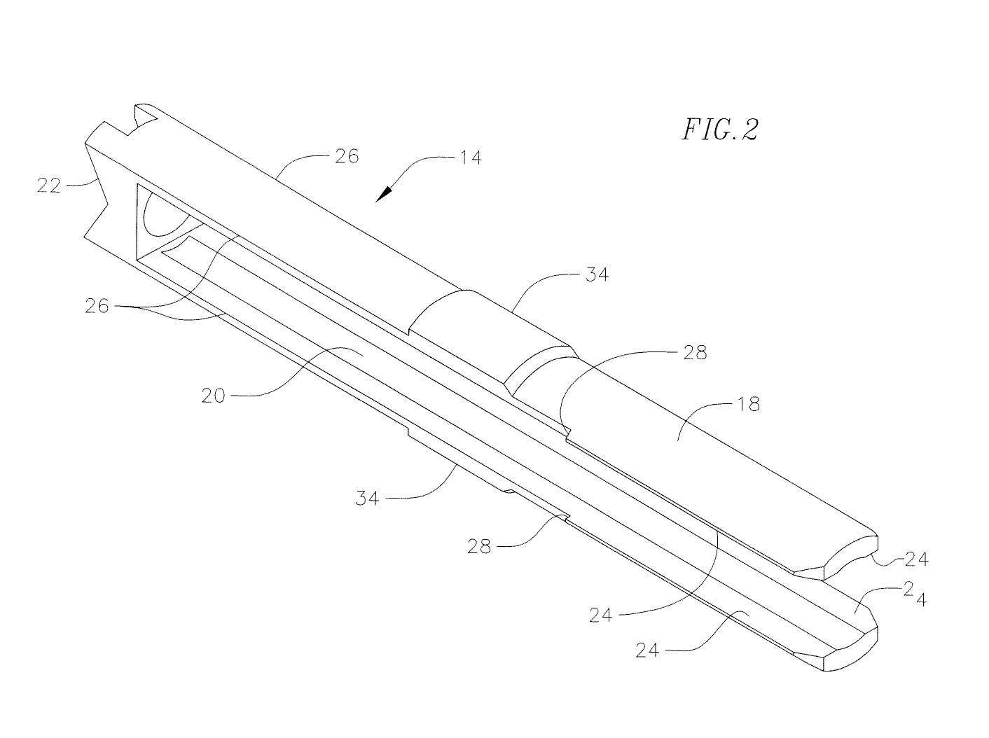

As seen in FIG. 1, each of the electrical contacts 10 are positioned within a bore 30 in a housing 32 or probe plate, depending upon the application. To maintain the electrical contact 10 within the bore 30, a raised portion 34 is positioned on each leg of both components to provide an enlarged diameter section which would be received within a larger diameter section 36 within each bore 30. Raised portion 34 allows the contact assembly to be retained in the housing 32 without falling out. In addition to raised portion 34 on each leg of the components, alternative methods for retaining the electrical contact within the bore 30 of the housing include a dimple 38 as shown in FIG. 3 or a tab 40 as shown in FIG. 4. The tab 38 and tab 40 are formed on each leg which would the retain the contact within enlarged diameter 36 in bore 30.

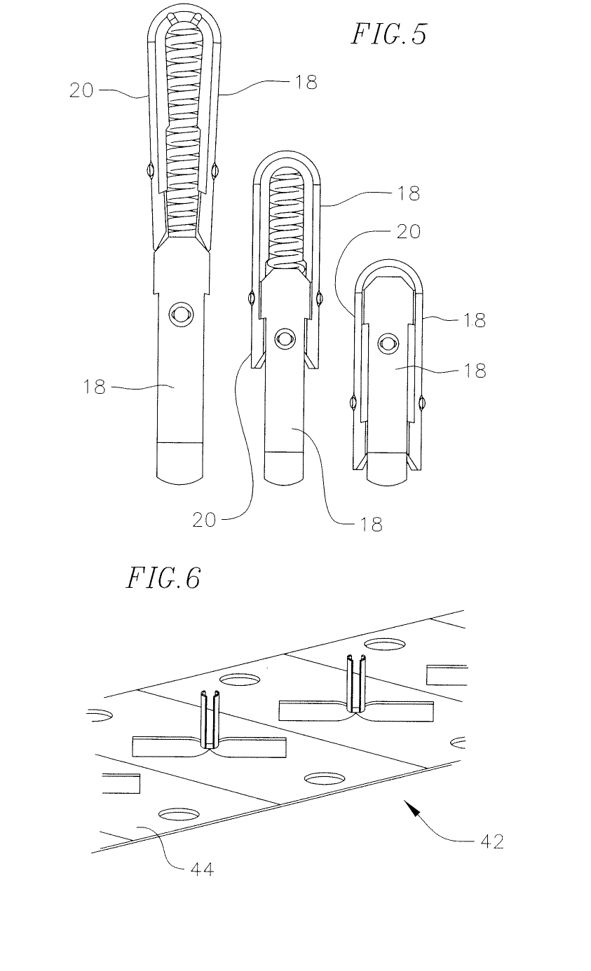

Each of the two components 12 and 14 are maintained in contact with each other by fabricating each component in such a fashion that the distance between the internal contact surfaces is smaller than the distance between the external contact surfaces, i.e. a contact surface can be manufactured at an angle. As shown in FIG. 5, an alternative method of maintaining contact between components 12 and 14 is to manufacture each component such that the legs 18 and 20 are manufactured to be tapered with respect to one another. In essence, tapered external contact surfaces increase the amount of contact as the assembly is compressed by forcing the opposing component leg portions apart.

Manufacturing the components 12 and 14 of the present invention can be by stamping 42 from a sheet 44 as shown in FIG. 6. Other methods for manufacturing could include turning, injection molding, layering and coining. Each component 12 and 14 will generally be manufactured in a cylindrical fashion, however other geometrical shapes such as square, rectangular are possible depending upon the specific manufacturing technique utilized. In addition, the contact portion 22 can be fully cylindrical in a portion beyond the length of the mating legs 18 and 20.

The sliding surface 24 and receiving surface 26 of each component 12 and 14 can provide up to eight points of contact that carry electrical current through the assembly as shown in FIG. 2. Alternatively, the number of contact points for a single electrical contact can vary by having a different number of contacts for each of the components 12 and 14.

Although the present invention has been described with respect to various embodiments thereof, it is to be understood that changes and modifications can be made which are within the full intended scope of the invention as hereinafter claimed.

What is claimed is:

1. An electrical contact comprising:
a first U-shaped contact component;
a second U-shaped contact component orthogonally connected to the first U-shaped contact component; and
a compression spring positioned within an internal volume created by the first and second U-shaped contact components.

2. The contact of claim 1 further comprising means for interlocking the first U-shaped contact component and the second U-shaped contact component.

3. The contact of claim 2, wherein the means for interlocking includes sliding surfaces along the edges of the first and second U-shaped contact components engaging an extended portion along the sliding surfaces.

4. The contact of claim 1 further comprising means for retaining the contact within a bore in a housing.

5. The contact of claim 4 wherein the means for retaining the contact is an enlarged diameter portion extending around the first and second U-shaped contact components.

6. The contact of claim 4 wherein the means for retaining the contact is at least one dimple on at least one of the first U-shaped contact component and the second U-shaped contact component.

7. The contact of claim 4 wherein the means for retaining the contact is at least one tab on at least one of the first U-shaped contact component and the second U-shaped component.

8. The contact of claim 1 wherein the first U-shaped contact component and the second U-shaped contact component are held in contact with each other by having internal smaller contact surfaces that external contact surfaces.

9. The contact of claim 1 wherein the first U-shaped contact component and the second U-shaped contact component are held in contact with each other by having tapered external contact services which increase contact by compression forces.

10. The contact of claim 1 wherein each first and second U-shaped contact component has at least one test pad contact surface.

11. A spring probe comprising:
a first component having a contact surface and a leg extending from either side of the contact surface;
a second component identical to the first component rotationally engaged with the first component to form an internal volume within the spring probes; and
a spring position within the internal volume.

12. The spring probe of claim 11 further comprising means for latching the legs of each of the first component and the second component together.

13. The spring probe of claim 12 wherein the means for latching include sliding surfaces along each side edge of the legs of the first and second components which engage an extended portion along the sliding surfaces.

14. The spring probe of claim 11 further comprising means for retaining a spring probe within a bore of a housing.

15. The spring probe of claim 14 wherein the means for retaining the spring probe is an enlarged diameter portion around the legs of the first and second components.

16. The spring probe of claim 14 wherein the means for retaining the spring probe within a bore in the housing is at least one dimple on the legs of at least one of the first or second component.

17. The spring probe of claim 14 wherein the means for retaining the spring probe within a bore in the housing is at least one tab on the legs of at least one of the first and second components.

18. The spring probe of claim 1 wherein the first component and a second component are held in contact with each other by having smaller internal contact surfaces than external contact surfaces along the legs.

19. The spring probe of claim 11 wherein the first component and second component are held in contact with each by having tapered external contact surfaces along the legs which increase contact by compression forces.

20. The spring probe of claim 11 wherein each of the first component and the second component have one or more test pad contact surfaces.
